(19) United States
(12) Patent Application Publication
(10) Pub. No.: US 2015/0222245 A1
(43) Pub. Date: Aug. 6, 2015

(54) METHOD FOR MANUFACTURING VIBRATING ELEMENT, VIBRATING ELEMENT, ELECTRONIC DEVICE, ELECTRONIC APPARATUS, AND MOVING OBJECT

(71) Applicant: Seiko Epson Corporation, Tokyo (JP)

(72) Inventor: Fumio ICHIKAWA, Suwa (JP)

(21) Appl. No.: 14/612,699

(22) Filed: Feb. 3, 2015

(30) Foreign Application Priority Data
Feb. 6, 2014 (JP) 2014-021138

(51) Int. Cl. H03H 9/215; H03H 3/007

(52) U.S. Cl. CPC H03H 9/215; H03H 3/007

(57) ABSTRACT

A method for manufacturing a vibrating element includes: providing, on a substrate, a first protective layer and a second protective layer; disposing the substrate in an apparatus including an energy-beam emitting unit for dry etching; and etching, using an energy beam emitted from the energy-beam emitting unit, the substrate on which the first protective layer and the second protective layer are disposed on one side relative to an intersection point at which a center of the energy-beam emitting unit and the substrate intersect each other in a plan view of the substrate. When a distance between the intersection point and the first protective layer is shorter than a distance between the intersection point and the second protective layer, a width of the first protective layer in a direction intersecting the extending direction of the vibrating arm is made narrower than a width of the second protective layer.

### BACKGROUND

1. Technical Field

The present invention relates to a method for manufacturing a vibrating element, a vibrating element, an electronic device, an electronic apparatus, and a moving object.

2. Related Art

Heretofore, angular velocity sensors have been used in techniques to autonomously control the attitude of ships, aircraft, rockets, and the like. Recently, the angular velocity sensors have been used for car body control in vehicles, self-position detection of car navigation systems, vibration control correction (so-called camera shake correction) of digital cameras, video camcorders, and mobile phones, and the like. As these electronic apparatuses are downsized, downsizing and low-profiling (thinning) of the angular velocity sensors are demanded.

In contrast, when a vibrating element including vibrating arms for drive or detection, which is used for an angular velocity sensor, is downsized, the area of an electrode provided in each of the vibrating arms is reduced. Therefore, a Q value is reduced, which causes a problem of deterioration in detection sensitivity. Therefore, JP-A-2009-156832 discloses a method for improving the detection sensitivity by providing a groove portion in each of the vibrating arms to increase an electric field efficiency and the Q value.

However, in the case where the outer shape or groove of the vibrating arm is formed by dry etching or the like from one main surface of the vibrating arm, when the vibrating arm is caused to perform flexural vibration in which the vibrating arm is displaced parallel to the main surface, oblique vibration is superimposed on the flexural vibration due to the influence of an inclined portion that is formed at a side surface of the vibrating arm. Therefore, the vibration leaks to a base portion that holds the vibrating arm, which causes a problem of a reduced Q value.

### SUMMARY

An advantage of some aspects of the invention is to solve at least a part of the problems described above, and the invention can be implemented as the following forms or application examples.

### APPLICATION EXAMPLE 1

This application example is directed to a method for manufacturing a vibrating element including a vibrating arm, a groove portion provided in the vibrating arm, a first thickened portion provided on one side of the groove portion in a direction intersecting an extending direction of the vibrating arm, in a plan view of the vibrating arm, and a second thickened portion provided on the side opposite to the one side, the method including: providing, on a substrate, a first protective layer for forming the first thickened portion and a second protective layer for forming the second thickened portion; disposing the substrate in an apparatus including an energy-beam emitting unit for dry etching; and etching, using an energy beam emitted from the energy-beam emitting unit, the substrate on which the first protective layer and the second protective layer are disposed on one side relative to an intersection point at which a center of the energy-beam emitting unit and the substrate intersect each other in a plan view of the substrate, wherein when a distance between the intersection point and the first protective layer is shorter than a distance between the intersection point and the second protective layer, a width of the first protective layer in a direction intersecting the extending direction of the vibrating arm is narrower than a width of the second protective layer in the direction intersecting the extending direction of the vibrating arm.

According to this application example, deterioration in the Q value of the vibrating element due to the influence of an inclined portion that is produced at one side surface of the vibrating arm is suppressed by forming the vibrating element by the manufacturing method in which the center of the groove portion is shifted toward the side surface side where the inclined portion is produced, so that it is possible to manufacture a vibrating element that suppresses oblique vibration occurring due to the inclined portion and has a high Q value.

### APPLICATION EXAMPLE 2

This application example is directed to the method for manufacturing the vibrating element according to the application example described above, wherein the method further includes: providing a third protective layer between the first protective layer and the second protective layer in the plan view of the substrate; and forming at least a portion of an outer shape of the vibrating arm using the energy beam.

According to this application example, since the third protective layer is provided between the first protective layer and the second protective layer, it is possible to avoid the generation of steps on an outside surface (outer shape) of the vibrating arm due to pattern misalignment between the third protective layer, and the first protective layer and the second protective layer, so that there is an advantageous effect in that the outer shape of the vibrating arm can be accurately formed.

### APPLICATION EXAMPLE 3

This application example is directed to the method for manufacturing the vibrating element according to the application example described above, wherein the method further includes: providing, before the forming of the protective layers, a third protective layer for forming an outer shape of the vibrating arm; and forming at least a portion of the outer shape of the vibrating arm using the energy beam.

According to this application example, the groove portion is not first formed, but the outer shape of the vibrating arm is formed, and then, the formation of the groove portion is performed. The outer shape of the vibrating arm is first formed, and then, the first and second protective layers are provided, whereby there is an advantageous effect in that it is easy to control the positions where the first and second protective layers are provided according to the outer shape.

### APPLICATION EXAMPLE 4

This application example is directed to the method for manufacturing the vibrating element according to the application example described above, wherein the substrate is a quartz crystal substrate.

According to this application example, the vibrating element is manufactured using a quartz crystal substrate, whereby it is possible to obtain a vibrating element having excellent temperature characteristics and a high Q value. Moreover, since it is possible to manufacture a vibrating element including a vibrating arm for drive and a vibrating arm for detection each of which has excellent temperature characteristics and a high Q value, there is an advantageous effect in that an angular velocity sensor having high accuracy can be obtained.

### APPLICATION EXAMPLE 5

This application example is directed to the method for manufacturing the vibrating element according to the application example described above, wherein the extending direction of the vibrating arm is along a Y-axis direction of the quartz crystal substrate.

According to this application example, the vibrating element is manufactured such that the extending direction of the vibrating arm is along the Y-axis direction of the quartz crystal substrate, so that it is possible to obtain a vibrating element that has excellent temperature characteristics, a high Q value, and flexural vibration. Moreover, it is possible to manufacture a vibrating element composed of a vibrating arm for drive that has excellent temperature characteristics, a high Q value, and flexural vibration, and a vibrating arm for detection that has excellent temperature characteristics, high detection sensitivity, and flexural vibration. Therefore, there is an advantageous effect in that an angular velocity sensor having higher accuracy can be obtained.

### APPLICATION EXAMPLE 6

This application example is directed to a vibrating element including: a vibrating arm; a groove portion provided in the vibrating arm; a first thickened portion provided on one side of the groove portion in a direction intersecting an extending direction of the vibrating arm, in a plan view of the vibrating arm, and a second thickened portion provided on the side opposite to the one side, the first thickened portion having a width narrower than a width of the second thickened portion; and an inclined portion provided at an outside surface of the first thickened portion in a cross-sectional view intersecting the extending direction of the vibrating arm.

According to this application example, in the first thickened portion and the second thickened portion that constitute the groove portion, the width of the first thickened portion on the side surface side where the inclined portion is formed is made narrower than the width of the second thickened portion, so that the center of the groove portion can be shifted toward the side where the inclined portion is formed. Therefore, it is possible to manufacture a vibrating element that suppresses oblique vibration occurring due to the inclined portion and has a high Q value.

### APPLICATION EXAMPLE 7

This application example is directed to an electronic device including: the vibrating element according to the application example described above; and a circuit element.

According to this application example, since the vibrating element that has a high Q value and the circuit element that stably oscillates the vibrating element are included, there is an advantageous effect in that an electronic device that has stable oscillation characteristics can be obtained.

### APPLICATION EXAMPLE 8

This application example is directed to an electronic apparatus including the vibrating element according to the application example described above.

According to this application example, there is an advantageous effect in that it is possible to configure an electronic apparatus including the vibrating element that suppresses unnecessary vibration and has a high Q value.

### APPLICATION EXAMPLE 9

This application example is directed to a moving object including the vibrating element according to the application example described above.

According to this application example, there is an advantageous effect in that it is possible to configure a moving object including the vibrating element that suppresses unnecessary vibration and has a high Q value.

### BRIEF DESCRIPTION OF THE DRAWINGS

The invention will be described with reference to the accompanying drawings, wherein like numbers reference like elements.

FIGS. 1A and 1B are schematic views showing a structure of a vibrating element according to an embodiment of the invention, in which FIG. 1A is a plan view, and FIG. 1B is a cross-sectional view taken along the line A-A.

FIGS. 2A and 2B are schematic views for explaining the manufacturing process of the vibrating element, in which FIG. 2A is a schematic view of a dry etching apparatus, and FIG. 2B is a cross-sectional view of a portion B of a substrate after being processed by dry etching.

FIGS. 3A and 3B are schematic views for explaining a vibration state of a vibrating element provided with a groove portion at the central portion of a vibrating arm, in which FIG. 3A is a cross-sectional view of the vibrating arm, and FIG. 3B is a cross-sectional view of the vibrating arm showing the vibration state.

FIGS. 4A and 4B are schematic views for explaining the vibration state of the vibrating element provided with the groove portion at the central portion of the vibrating arm, in which FIG. 4A is a cross-sectional view schematically showing the vibrating arm, and FIG. 4B is a cross-sectional view of the vibrating arm.

FIGS. 5A and 5B are schematic views for explaining a vibration state of the vibrating element according to the embodiment of the invention, in which FIG. 5A is a cross-sectional view schematically showing a vibrating arm, and FIG. 5B is a cross-sectional view of the vibrating arm.

FIGS. 6A to 6F are step diagrams sequentially showing manufacturing steps of the vibrating element according to the embodiment of the invention.

FIGS. 7A and 7B are schematic views showing a structure of an electronic device including the vibrating element according to the invention, in which FIG. 7A is a plan view, and FIG. 7B is a cross-sectional view taken along the line C-C.

FIGS. 8A and 8B are schematic views each showing an electronic apparatus including the vibrating element according to the invention, in which FIG. 8A is a perspective view showing a configuration of a mobile (or notebook) personal computer, and FIG. 8B is a perspective view showing a configuration of a mobile phone (including a PHS).

FIG. 9 is a perspective view showing a configuration of a digital camera as an electronic apparatus including the vibrating element according to the invention.

FIG. 10 is a perspective view showing a configuration of an automobile as a moving object including the vibrating element according to the invention.

### DESCRIPTION OF EXEMPLARY EMBODIMENTS

Hereinafter, embodiments of the invention will be described in detail based on the drawings.

### Embodiments

### Vibrating Element

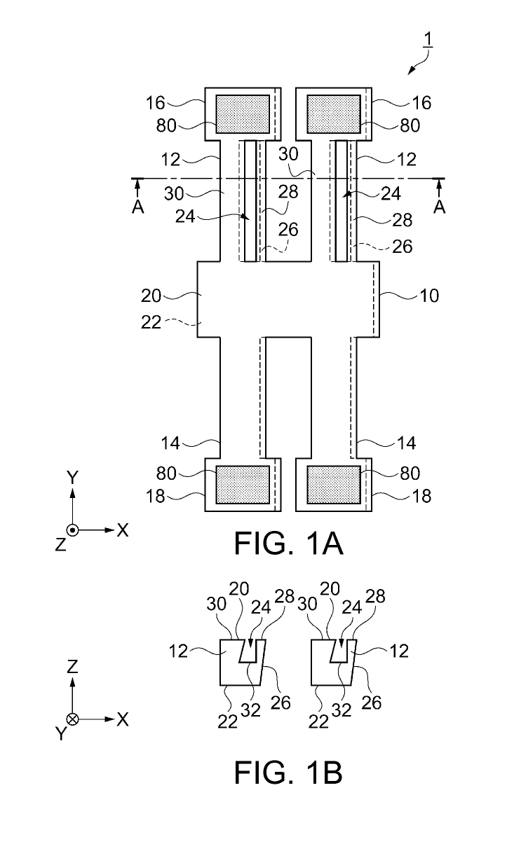

As an example of a vibrating element 1 according to an embodiment of the invention, a vibrating element having a structure called an H type, which is used for an angular velocity sensor, will be described with reference to FIGS. 1A and 1B.

FIGS. 1A and 1B are schematic views showing the structure of the vibrating element 1 according to the embodiment of the invention, in which FIG. 1A is a plan view, and FIG. 1B is a cross-sectional view taken along the line A-A shown in FIG. 1A. Drive electrodes or detection electrodes are not shown in the drawings. Moreover, in the drawings described below, an X-axis, a Y-axis, and a Z-axis are shown as three axes orthogonal to each other for convenience of description. The tip end side of each arrow shown in the drawings is defined as a “positive side”, while the base end side thereof is defined as a “negative side”. Moreover, a direction parallel to the X-axis is referred to as an “X-axis direction; a direction parallel to the Y-axis is referred to as a “Y-axis direction”; and a direction parallel to the Z-axis is referred to as a “Z-axis direction”. Further, in a plan view as viewed from the Z-axis direction, a surface in the positive Z-axis direction is referred to as a first main surface 20 or upper surface, while a surface in the negative Z-axis direction is referred to as a second main surface 22 or lower surface.

The vibrating element 1 is formed of a piezoelectric material such as quartz crystal, and has a double-side tuning fork-type (H-type) structure as shown in FIG. 1A. The vibrating element 1 includes a substantially rectangular base portion 10 at the center, a pair of vibrating arms 12 for drive that extend, from the base portion 10, parallel to each other side by side on one side, and a pair of vibrating arms 14 for detection that extend parallel to each other side by side on the opposite side. The extending direction of the vibrating arms 12 and 14 is formed along the Y-axis direction of a quartz crystal substrate as a constituent material.

Drive electrodes (not shown) are formed on surfaces of the vibrating arm 12 for drive in order to cause the vibrating arm 12 for drive to flexurally vibrate in an in-plane direction along the first main surface 20 and the second main surface 22 in an drive mode, for example, in an XY plane parallel to the first main surface 20 and the second main surface 22. Detection electrodes (not shown) are formed on surfaces of the vibrating arm 14 for detection in order to detect a potential difference that is generated when the vibrating arm 14 for detection flexurally vibrates in a direction crossing the first main surface 20 and the second main surface 22 in a detection mode, for example, in the Z-axis direction perpendicular to the first main surface 20 and the second main surface 22.

In the drive mode, when a predetermined AC voltage is applied to the drive electrodes, the vibrating arms 12 for drive flexurally vibrate in opposite directions along the XY in-plane direction, that is, in directions in which the vibrating arms 12 move close to or away from each other.

In this state, when the vibrating element 1 for use in an angular velocity sensor rotates about the Y-axis as the longitudinal direction, the vibrating arms 12 for drive flexurally vibrate in opposite directions along an out-of-plane direction perpendicular to the first main surface 20 and the second main surface 22, that is, along the Z-axis direction due to the action of a Coriolis force that is generated according the angular velocity. The vibrating arms 14 for detection resonate with the vibration in the Z-axis direction, and flexurally vibrate in opposite directions along the same Z-axis direction in the detection mode. At this time, the vibration direction of the vibrating arm 14 for detection is opposite in phase from the vibration direction of the vibrating arm 12 for drive.

By extracting a potential difference that is generated between the detection electrodes of the vibrating arms 14 for detection in the detection mode, the angular velocity of the vibrating element 1 about the Y-axis is obtained.

The vibrating arm 12 for drive includes a groove portion 24 provided with a bottomed groove from the first main surface 20 toward the second main surface 22 on the side opposite to the first main surface 20. In a cross-sectional view (XZ plane view) of the vibrating arm 12 in a direction perpendicular to the extending direction of the vibrating arm 12, the width (length in the X-axis direction) of the second main surface 22 is narrower than the width (length in the X-axis direction) of the first main surface 20, and an inclined portion 26 that is in contact with the first main surface 20 and the second main surface 22 is formed. Moreover, the width (length in the X-axis direction) of a first thickened portion 28 constituting the groove portion 24 is formed to be narrower than the width (length in the X-axis direction) of a second thickened portion 30, and the center of the width (length in the X-axis direction) of the groove portion 24 is shifted toward the positive X-axis direction relative to the center of the width (length in the X-axis direction) of the vibrating arm 12 in the first main surface 20. Further, the groove portion is formed such that the width (length in the X-axis direction) thereof is wider on a bottom edge 32 side of the groove portion 24 than on the first main surface 20 side. The groove portion 24 is provided for increasing an electric field efficiency of the vibrating arm 12, and may be provided in the vibrating arm 14 for detection.

The vibrating arms 12 and 14 are respectively provided with weight portions 16 and 18 at tips so that the occurrence of a high-order vibration mode can be suppressed to stabilize a vibration frequency even when the length of the vibrating arm is shortened. Moreover, by providing the weight portions 16 and 18, downsizing of the vibrating element 1 can be achieved, or the vibration frequencies of the vibrating arms 12 and 14 can be lowered. The weight portions 16 and 18 may each have, as necessary, a plurality of widths (lengths in the X-axis direction), or may be omitted.

An electrode 80 is formed on the second main surface 22 of each of the weight portions 16 and 18. The electrode 80 is partially evaporated by irradiation with a laser beam, whereby the vibration frequencies of the vibrating arms 12 and 14 can be adjusted. If the vibrating arms 12 and 14 that are paired with each other are adjusted so as to have the same vibration frequency, vibration leakage to the base portion 10 can be reduced to thereby improve the Q value. The forming position of the electrode 80 is not limited to the second main surface 22, and may be the first main surface 20 or both of the first main surface 20 and the second main surface 22.

For the structure of the vibrating element 1 according to the embodiment of the invention, the both-side tuning fork-type (H-type) structure has been described as an example. In addition to this structure, a general tuning fork-type structure, a double tuning fork-type structure, and a double T-type structure that drive flexural vibration may be adopted.

The constituent material of the vibrating element 1 according to the embodiment of the invention is not limited to a piezoelectric material such as quartz crystal, and examples thereof include lithium tantalate (LiTaO₃), lithium niobate (LiNbO₃), potassium niobate (KNbO₃), lithium tetraborate (Li₂B₄O₇), barium titanate (BaTiO₃), PZT (lead zirconate titanate), quartz, and silicon.

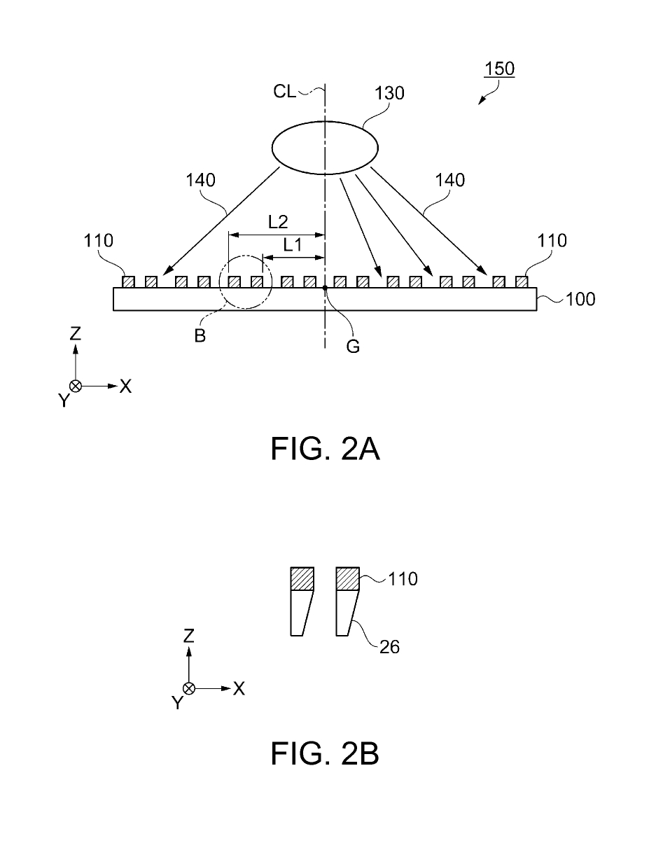

Next, the reason why the inclined portion 26 that is in contact with the first main surface 20 and the second main surface 22 is formed only at one of side surfaces of the vibrating arm 12 in a cross-section (XZ plane), in a cross-sectional view (XZ plane view) in the direction perpendicular to the extending direction of the vibrating arm 12, will be described with reference to FIGS. 2A and 2B.

FIGS. 2A and 2B are schematic views for explaining the manufacturing process of the vibrating element 1, in which FIG. 2A is a schematic view of a dry etching apparatus 150, and FIG. 2B is a cross-sectional view of a portion B of a substrate 100 shown in FIG. 2A after being processed by dry etching.

As shown in FIG. 2A, the dry etching apparatus 150 for forming the vibrating element 1 by dry etching the substrate 100 includes an energy-beam emitting unit 130 disposed at the central portion. With energy beams 140 radially emitted from the energy-beam emitting unit 130, the dry etching apparatus 150 etches portions of the surface of the substrate 100 that are not covered with protective layers 110, that is, exposed portions. Thereafter, the energy beam 140 is emitted for a long time to thereby penetrate through the substrate 100, so that the outer shape of the vibrating element 1 can be formed. Here, in a cross-section (XZ plane) of the substrate 100 through which the energy beam 140 penetrates, the portion B has a cross-sectional shape having the inclined portion 26 at the side surface on the positive X-axis side as shown in FIG. 2B.

The reason is as follows. Relative to an intersection point G at which a center CL of the energy-beam emitting unit 130 and the substrate 100 intersect each other, when distances L1 and L2 from the intersection point G to the protective layers 110 increase on the negative X-axis direction side of the intersection point G, the angle of the energy beam 140 emitted from the energy-beam emitting unit 130 is from a substantially right angle to an acute angle relative to the main surface of the substrate 100. Therefore, etching is not performed at a substantially right angle relative to the main surface of the substrate 100, so that the portion B is etched into the cross-sectional shape having the inclined portion 26 at the side surface on the positive X-side. Conversely, on the positive X-axis direction side of the intersection point G, the portion B is etched into a cross-sectional shape having the inclined portion 26 at the side surface on the negative X-side.

Moreover, the angle of the energy beam 140 relative to the main surface of the substrate 100 becomes more acute with increasing the distance from the intersection point G. Therefore, in the cross-sectional shape, the width (length in the X-axis direction) of the portion B on the side where the protective layer 110 is not formed is much shorter compared to the width (length in the X-axis direction) of the portion B on the protective layer 110 side.

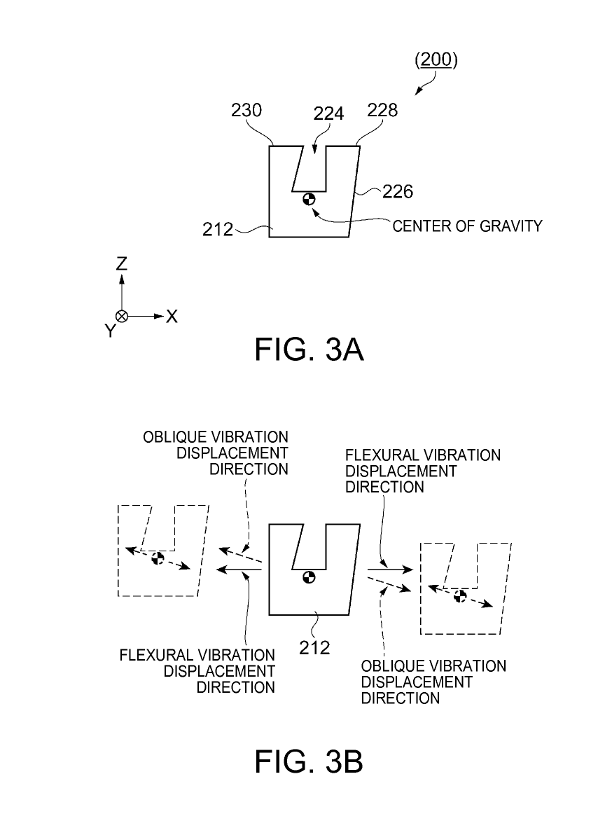

Next, a vibration state of a vibrating element 200 including an inclined portion 226 and provided with a groove portion 224 at the central portion of a vibrating arm 212 will be described with reference to FIGS. 3A and 3B.

FIGS. 3A and 3B are schematic views for explaining the vibration state of the vibrating element 200 provided with the groove portion 224 at the central portion of the vibrating arm 212, in which FIG. 3A is a cross-sectional view of the vibrating arm 212, and FIG. 3B is a cross-sectional view of the vibrating arm 212 showing the vibration state.

As shown in FIG. 3A, the vibrating arm 212 is formed such that the widths (lengths in the X-axis direction) of upper surfaces of a first thickened portion 228 and a second thickened portion 230 that constitute the groove portion 224 are substantially the same to each other, and that the inclined portion 226 is formed at a side surface on the positive X-axis side. When the vibrating arm 212 including the inclined portion 226 is flexurally vibrated where the vibrating arm 212 is displaced in the X-axis direction, the center of gravity of a cross-section (XZ plane) of the vibrating arm 212 is displaced in directions indicated by the dashed arrows due to the influence of the inclined portion 226 as shown in FIG. 3B. That is, the vibrating arm 212 performs flexural vibration on which oblique vibration is superimposed. Therefore, in the case of configuring the vibrating element 200 including a pair of vibrating arms 212, the pair of vibrating arms 212 move close to or away from each other, so that vibration displacement occurring at the base portion 10 (refer to FIG. 1A) is canceled out and thus a high Q value is maintained; however, the vibration displacement cannot be canceled out at the base portion due to the superposition of the oblique vibration, the vibration leaks from the base portion, and thus the Q value is reduced to cause a problem.

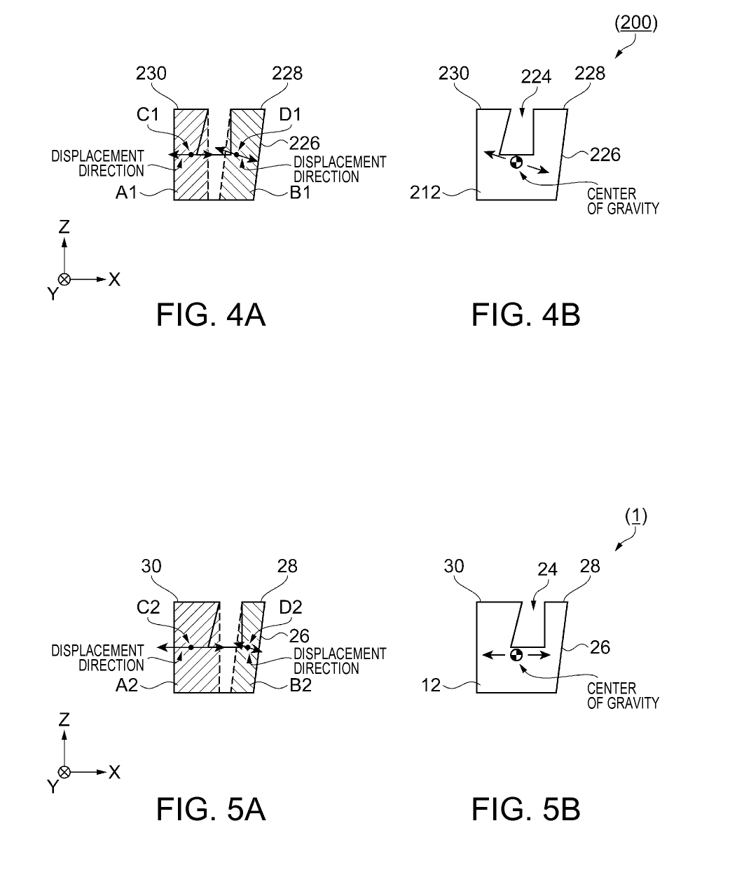

Next, the influences of the inclined portions 26 and 226 formed respectively in the vibrating arms 12 and 212 on vibrations will be described in detail with reference to FIGS. 4A to 5B.

FIGS. 4A and 4B are schematic views for explaining the vibration state of the vibrating element 200 provided with the groove portion 224 at the central portion of the vibrating arm 212, in which FIG. 4A is a cross-sectional view schematically showing the vibrating arm 212, and FIG. 4B is a cross-sectional view of the vibrating arm 212. FIGS. 5A and 5B are schematic views for explaining the vibration state of the vibrating element 1 according to the embodiment of the invention, in which FIG. 5A is a cross-sectional view schematically showing the vibrating arm 12, and FIG. 5B is a cross-sectional view of the vibrating arm 12.

First, the vibration state of the vibrating element 200 including the inclined portion 226 and provided with the groove portion 224 at the central portion of the vibrating arm 212 will be described with reference to FIGS. 4A and 4B.

When it is assumed, as shown in FIG. 4A, that a cross-section (XZ plane) of the vibrating arm 212 including the inclined portion 226 is configured to be separated into a rectangular region A1 having the width (length in the X-axis direction) of the upper surface of the second thickened portion 230 and a parallelogram-shaped region B1 having the width (length in the X-axis direction) of the upper surface of the first thickened portion 228, a displacement direction at a central point C1 of the region A1 is the X-axis direction, which is the same as a displacement direction in usual flexural vibration. However, since charge is generated in a direction orthogonal to the inclined portion 226, a displacement direction at a central point D1 of the region B1 is a direction orthogonal to the inclined portion 226, which is the same direction as the charge generated direction, and therefore, flexural vibration on which oblique vibration is superimposed is caused. Since the width (length in the X-axis direction) of the upper surface of the second thickened portion 230 in the region A1 is substantially equal to the width (length in the X-axis direction) of the upper surface of the first thickened portion 228 in the region B1, displacement vectors at the respective central points C1 and D1 are deemed as substantially equal to each other. Therefore, as shown in FIG. 4B, the center of gravity of the cross-section (XZ plane) of the vibrating arm 212 is displaced in an intermediate direction between the displacement direction at the central point C1 of the region A1 and the displacement direction at the central point D1 of the region B1. Accordingly, the vibrating element 200 including the inclined portion 226 and provided with the groove portion 224 at the central portion of the vibrating arm 212 performs the flexural vibration on which the oblique vibration is superimposed.

Next, the vibration state of the vibrating element 1 according to the embodiment of the invention will be described with reference to FIGS. 5A and 5B.

When it is assumed, as shown in FIG. 5A, that a cross-section (XZ plane) of the vibrating arm 12 including the inclined portion 26 and provided with the groove portion 24 on the inclined portion 26 side of the central portion is configured to be separated into, similarly to FIG. 4A, a rectangular region A2 having the width (length in the X-axis direction) of the upper surface of the second thickened portion 30 and a parallelogram-shaped region B2 having the width (length in the X-axis direction) of the upper surface of the first thickened portion 28, a displacement direction at a central point C2 of the region A2 is the X-axis direction, which is a direction orthogonal to the side surface, and a displacement direction at a central point D2 of the region B2 is a direction orthogonal to the inclined portion 26. However, since the width (length in the X-axis direction) of the upper surface of the second thickened portion 30 in the region A2 is wider than the width (length in the X-axis direction) of the upper surface of the first thickened portion 28 in the region B2, a displacement vector at the central point C2 is greater compared to a displacement vector at the central point D2. Therefore, as shown in FIG. 5B, the X-axis direction as the displacement direction at the central point C2 of the region A2 is dominant, and the center of gravity of the cross-section (XZ plane) of the vibrating arm 12 is displaced substantially in the X-axis direction.

Therefore, by adopting the configuration of the vibrating arm 12 provided with the groove portion 24 on the inclined portion 26 side of the central portion, the oblique vibration due to the inclined portion 26 can be suppressed, and therefore, it is possible to obtain the vibrating element 1 having a high Q value. Moreover, when the configuration is applied to the vibrating element 1 of an angular velocity sensor, the oblique vibration occurring at the vibrating arm 12 for drive is suppressed, and an output signal (zero-point output) at the vibrating arm 14 for detection in the state where an angular velocity is not applied can be reduced. Therefore, it is possible to obtain an angular velocity sensor having high accuracy.

### Manufacturing Method

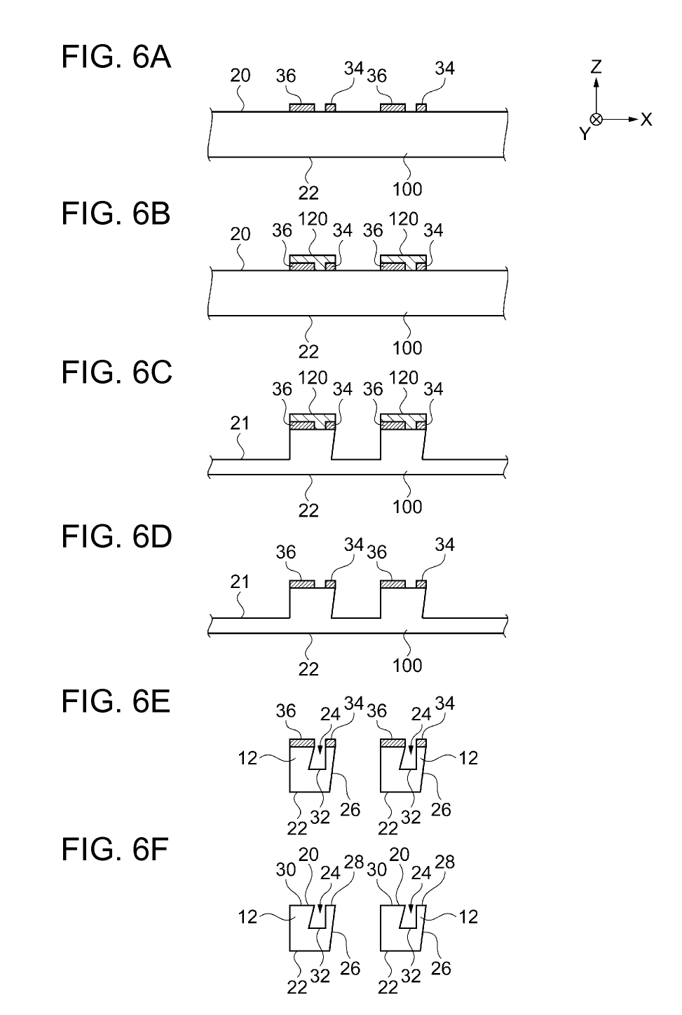

Next, a method for manufacturing the vibrating element 1 according to an embodiment of the invention will be described with reference to FIGS. 6A to 6F and, as necessary, with reference also to FIGS. 2A and 2B. For the description, the same constituting portions are denoted by the same reference numerals and signs, and a redundant description is omitted.

FIGS. 6A to 6F are step diagrams sequentially showing the manufacturing steps of the vibrating element 1 according to the embodiment of the invention. FIGS. 6A to 6F show the forms of the vibrating element 1 in the steps in cross-sectional views taken along the line A-A in FIG. 1A. Moreover, FIGS. 6A to 6F show the vibrating element 1 assumed to be formed in the vicinity of the portion B on the negative X-axis direction side of the intersection point G in FIG. 2A. Accordingly, a distance from the intersection point G to a first protective layer 34 is shorter than that to a second protective layer 36.

FIG. 6A: The substrate 100 formed of a piezoelectric material such as quartz crystal is prepared, and the first protective layer 34 for forming the first thickened portion 28 and the second protective layer 36 for forming the second thickened portion 30 are formed by collectively patterning in an outer shape processing region including the base portion 10 (refer to FIG. 1A) and the vibrating arm 12 and a forming region of the groove portion 24 on the first main surface 20 of the substrate 100. In a plan view of the substrate 100, relative to the intersection point G at which the center CL of the energy-beam emitting unit 130 for dry etching included in the dry etching apparatus 150 and the substrate 100 intersect each other, the first protective layer 34 is disposed on the short-distance side, and the second protective layer 36 is disposed on the long-distance side. Moreover, when a distance between the intersection point G and the first protective layer 34 is shorter than a distance between the intersection point G and the second protective layer 36, the width (length in the X-axis direction) of the first protective layer 34 in a direction intersecting the extending direction of the vibrating arm 12 is formed to be narrower than the width (length in the X-axis direction) of the second protective layer 36 in the direction intersecting the extending direction of the vibrating arm 12. Further, the extending direction of the vibrating arm 12 is along the Y-axis direction (mechanical axis direction of quartz crystal) of the substrate 100.

FIG. 6B: Next, a third protective layer 120 is formed by patterning on the first protective layer 34, the second protective layer 36, and the forming region of the groove portion 24. Here, the third protective layer 120 is patterned on the first protective layer 34 and the second protective layer 36 in order to protect the first protective layer 34 and the second protective layer 36 in etching described later. A method may also be adopted, in which the third protective layer 120 is provided between the first protective layer 34 and the second protective layer 36 in the plan view of the substrate, and at least a portion of the outer shape of each of the vibrating arms 12 and 14 is formed using the energy beam 140 described later. With the use of this method, compared to the method in which the third protective layer 120 is patterned between the first protective layer 34 and the second protective layer 36, it is possible to avoid the generation of steps on an outside surface (outer shape) of each of the vibrating arms 12 and 14 due to pattern misalignment between the third protective layer 120, and the first protective layer 34 and the second protective layer 36, so that the outer shape of each of the vibrating arms 12 and 14 can be accurately formed.

FIG. 6C: Next, the substrate 100 is disposed in the interior of the dry etching apparatus 150 including the energy-beam emitting unit 130, such as a RIE (Reactive Ion Etching) apparatus. The substrate 100 is placed by being sucked with the second main surface 22 side facing downward. Thereafter, an exposed surface of the substrate 100 is etched using the energy beam 140 emitted from the energy-beam emitting unit 130, in which etching is performed until a work surface 21 reaches a predetermined position (about 30% to 50% of the thickness (length in the Z-axis direction) of the substrate 100).

FIG. 6D: Next, the substrate 100 is taken from the interior of the dry etching apparatus 150, and the third protective layer 120 patterned in the forming region of the groove portion 24 is removed.

FIG. 6E: Next, the substrate 100 is disposed again in the interior of the dry etching apparatus 150, and then, the forming region of the groove portion 24 where the substrate 100 is exposed and the work surface 21 etched to the predetermined position are etched using the energy beam 140 emitted from the energy-beam emitting unit 130. The work surface 21 is etched until the energy beam penetrates through the substrate, and the forming region is etched until the depth (length in the Z-axis direction) of the groove portion 24 reaches about 50% to 70% of the thickness (length in the Z-axis direction) of the vibrating arm 12 (the substrate 100).

FIG. 6F: Next, the substrate 100 is taken from the interior of the dry etching apparatus 150, and the first protective layer 34 and the second protective layer 36 that are patterned on the upper surface of the base portion 10 (refer to FIG. 1A) or the vibrating arm 12 are removed.

Through the steps described above, the outer shape of the vibrating element 1 including the vibrating arm 12 provided with the groove portion 24 and the inclined portion is completed. Thereafter, the drive electrode, the detection electrode, the electrode 80 for frequency adjustment (refer to FIG. 1A), and the like, described above, are formed, whereby the vibrating element 1 is completed.

The manufacturing method according to the embodiment described above is a method for manufacturing the vibrating element 1, in which, first, the outer shape including the base portion 10 or the vibrating arm 12 is partially etched, and then, the outer shape and the groove portion 24 are etched together. The method is effective for shortening the time for etching. However, the invention is not limited to the method, and may adopt a method, in which, first, the outer shape is formed by etching, and then, the groove portion 24 is formed by etching.

That is, in the method, before the protective layer forming step in which the first protective layer 34 and the second protective layer 36 are formed, the third protective layer 120 for forming the outer shape of the base portion 10 or the vibrating arm 12 is provided, and the outer shape of the base portion 10 or the vibrating arm 12 is formed by etching using the energy beam 140 described above. Since the outer shape of the vibrating arm 12 is first formed, it is easy to control the positions where the first protective layer 34 and the second protective layer 36 are provided.

Moreover, a method may also be adopted, in which the groove portion 24 is first formed by etching, and then, the outer shape including the base portion 10 or the vibrating arm 12 is formed by etching. Also in this case, since the groove portion 24 is first formed, it is easy to control the position where the third protective layer 120 for forming the outer shape of the base portion 10 or the vibrating arm 12 is provided.

Through the manufacturing method described above, it is possible to manufacture the vibrating element 1 including the vibrating arm 12 in which, in the cross-section (XZ plane) intersecting the extending direction of the vibrating arm 12, the inclined portion 26 is included at one of side surfaces, and the width (length in the X-axis direction) of the first thickened portion 28 on the inclined portion 26 side, which constitutes the groove portion 24, is narrower than the width (length in the X-axis direction) of the second thickened portion 30. Therefore, since the oblique vibration due to the inclined portion 26 can be suppressed, the vibrating element 1 having a high Q value can be obtained. The other side surface is not limited to a vertical form, but may be inclined, in the cross-sectional (XZ plane) view. Moreover, when the embodiment is applied to the vibrating element 1 of an angular velocity sensor, the oblique vibration occurring at the vibrating arm 12 for drive is suppressed, an output signal (zero-point output) at the vibrating arm 14 for detection in the state where an angular velocity is not applied can be reduced, and therefore, an angular velocity sensor having high accuracy can be obtained.

### Electronic Device

Next, an electronic device 2 according to an embodiment of the invention, to which the vibrating element 1 is applied, will be described.

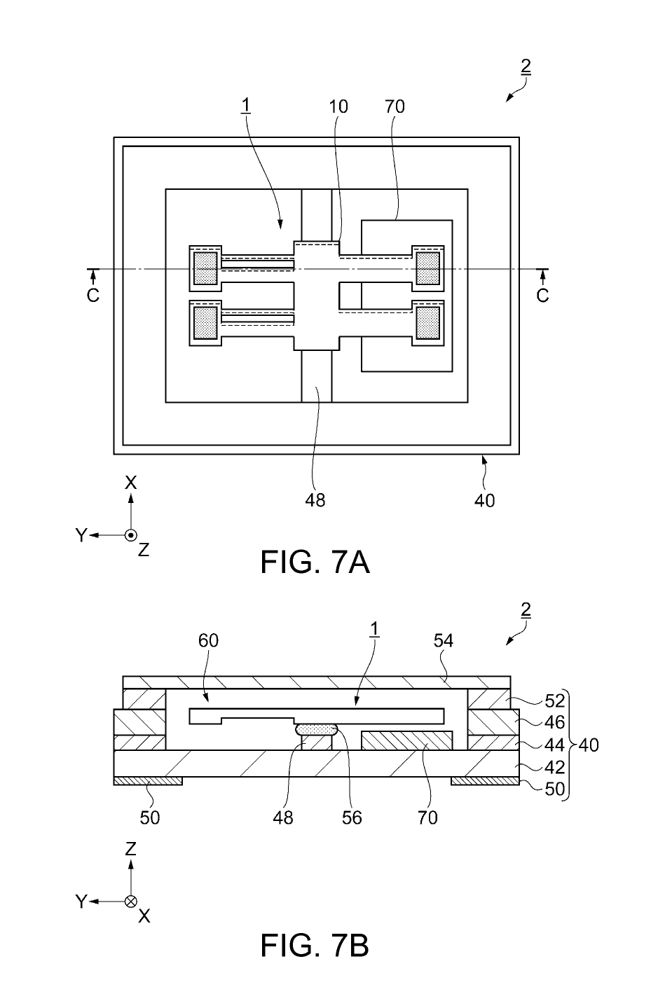

FIGS. 7A and 7B are schematic views showing a structure of the electronic device 2 including the vibrating element 1 according to the embodiment of the invention, in which FIG. 7A is a plan view, and FIG. 7B is a cross-sectional view taken along the line C-C shown in FIG. 7A. In FIG. 7A, for convenience of description of an internal configuration of the vibrating element 1, the electronic device 2 in the state where a lid member 54 is removed is shown. Moreover, for convenience of description, the X-axis, the Y-axis, and the Z-axis are shown as three axes orthogonal to each other. Further, for convenience of description, in a plan view as viewed from the Z-axis direction, a surface in the positive Z-axis direction is referred to as an upper surface, while a surface in the negative Z-axis direction is referred to as a lower surface.

As shown in FIGS. 7A and 7B, the electronic device 2 is composed of the vibrating element 1, a circuit element 70 for oscillating the vibrating element 1, a package main body 40 in which a recessed portion for accommodating the vibrating element 1 is formed, and the lid member 54 formed of glass, ceramic, metal, or the like. A cavity 60 to accommodate the vibrating element 1 is hermetically sealed so that a reduced-pressure atmosphere that is substantially a vacuum is established therein.

As shown in FIG. 7B, the package main body 40 is formed by stacking a first substrate 42, a second substrate 44, a third substrate 46, external terminals 50 and a sealing member 52. The plurality of external terminals 50 are formed on a bottom surface of the first substrate 42 on the outside. Electrode terminals (not shown) that are used for mounting the circuit element 70 and electrically conducted to the external terminals 50, or electrode terminals (not shown) that are electrically conducted to electrodes for drive of the vibrating element 1, are provided at predetermined positions on an upper surface of the first substrate 42 or an upper surface of a support portion 48 of the second substrate 44 via through-electrodes or inter-layer wiring (not shown). The third substrate 46 is a circular body obtained by removing the central portion thereof, in which the cavity 60 to accommodate the vibrating element 1 is formed. At an upper edge of the third substrate 46, the sealing member 52 such as low-melting-point glass is formed.

The lid member 54 is preferably formed of a light-transmissive material, for example, borosilicate glass or the like. The lid member 54 is bonded with the sealing member 52 to thereby hermetically seal the cavity 60 of the package main body 40. With this configuration, after sealing the lid of the package main body 40, the electrode 80 (refer to FIG. 1A) at the tip of the vibrating element 1 is externally irradiated with a laser beam through the lid member 54, and a portion of the electrode 80 (refer to FIG. 1A) is evaporated, whereby vibration frequency adjustment can be performed by a mass reduction method. When such vibration frequency adjustment is not performed, the lid member 54 can be formed of a metal material such as Kovar alloy.

The vibrating element 1 that is accommodated in the cavity 60 of the package main body 40 is bonded to an upper surface of the support portion 48 of the second substrate 44 via a bonding member 56 with the base portion 10 aligned to the upper surface of the support portion 48. Therefore, since the vibrating arm 12 for drive and the vibrating arm 14 for detection can be vibrated without contacting the first substrate 42, there is an advantageous effect in that it is possible to provide the electronic device 2 including the vibrating element 1 having a high Q value and stable vibration characteristics.

### Electronic Apparatuses

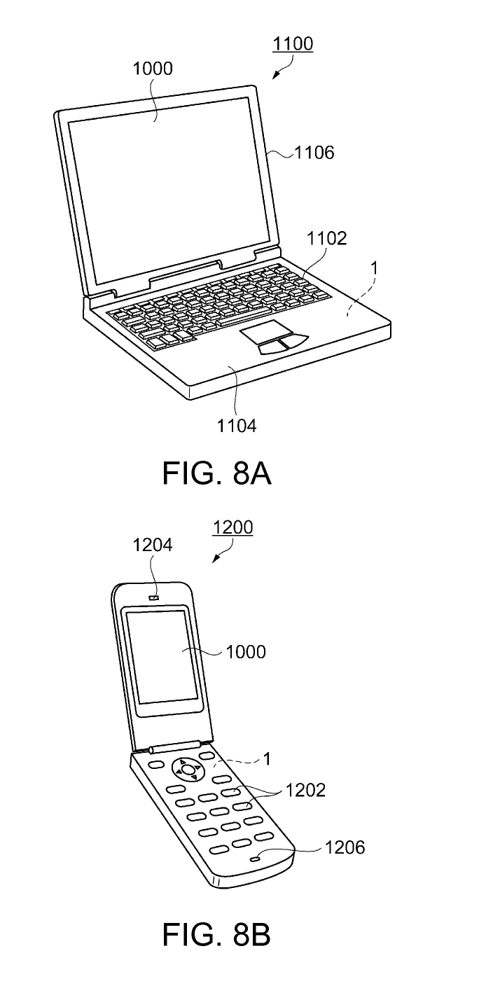

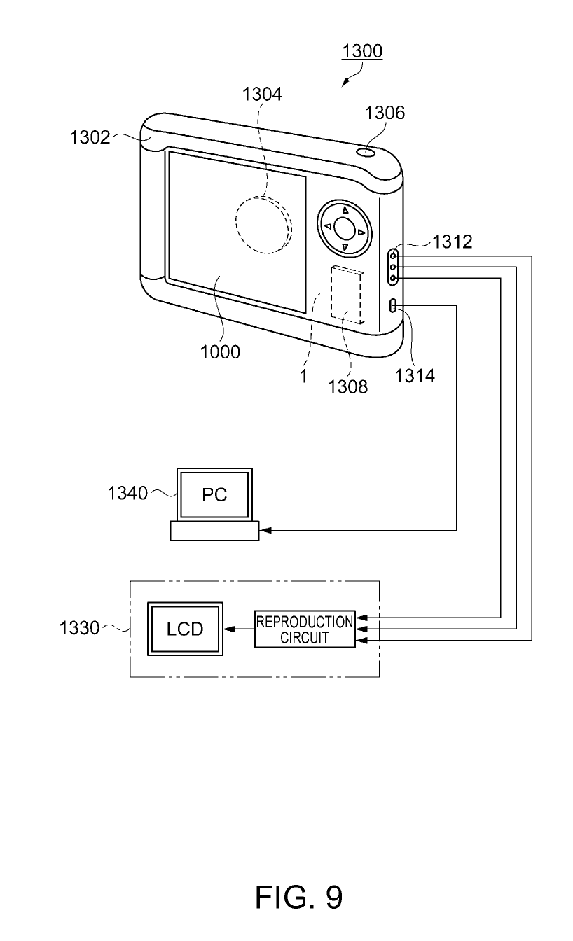

Next, electronic apparatuses according to an embodiment of the invention, to which the vibrating element 1 as an electronic component is applied, will be described based on FIGS. 8A to 9.

FIGS. 8A and 8B are schematic views each showing an electronic apparatus including the vibrating element 1 according to the embodiment of the invention, in which FIG. 8A is a perspective view showing a configuration of a mobile (or notebook) personal computer 1100, and FIG. 8B is a perspective view showing a configuration of a mobile phone 1200 (including a PHS).

In FIG. 8A, the personal computer 1100 is composed of a main body portion 1104 including a keyboard 1102, and a display unit 1106 including a display portion 1000. The display unit 1106 is rotatably supported relative to the main body portion 1104 via a hinge structure portion. Into the personal computer 1100, the vibrating element 1 as an electronic component that functions as a filter, a resonator, a reference clock, or the like is built.

In FIG. 8B, the mobile phone 1200 includes a plurality of operation buttons 1202, an earpiece 1204, and a mouthpiece 1206. The display portion 1000 is disposed between the operation buttons 1202 and the earpiece 1204. Into the mobile phone 1200, the vibrating element 1 as an electronic component (timing device) that functions as a filter, a resonator, an angular velocity sensor, or the like is built.

FIG. 9 is a perspective view showing a configuration of a digital camera 1300 as an electronic apparatus including the vibrating element 1 according to the embodiment of the invention. In FIG. 9, connections with external apparatuses are also shown in a simplified manner.

The digital camera 1300 photoelectrically converts an optical image of a subject with an imaging element such as a CCD (Charge Coupled Device) to generate imaging signals (image signals).

The display portion 1000 is provided on a back surface of a case (body) 1302 in the digital camera 1300, and configured to perform display based on the imaging signals generated by the CCD. The display portion 1000 functions as a finder that displays the subject as an electronic image. Moreover, on the front side (the rear side in the drawing) of the case 1302, a light receiving unit 1304 including an optical lens (imaging optical system) and the CCD is provided.

When a photographer confirms the subject image displayed on the display portion 1000 and presses down a shutter button 1306, imaging signals of the CCD at the time are transferred to and stored in a memory 1308. In the digital camera 1300, a video signal output terminal 1312 and an input/output terminal 1314 for data communication are provided on a side surface of the case 1302. Then, as shown in the drawing, a television monitor 1330 and a personal computer 1340 are connected as necessary to the video signal output terminal 1312 and the input/output terminal 1314 for data communication, respectively. Further, the imaging signals stored in the memory 1308 are output to the television monitor 1330 or the personal computer 1340 by a predetermined operation. Into the digital camera 1300, the vibrating element 1 as an electronic component that functions as a filter, a resonator, an angular velocity sensor, or the like is built.

As described above, the vibrating element 1 that suppresses the occurrence of unnecessary vibration and has a high Q value is utilized as an electronic component, whereby it is possible to provide an electronic apparatus with higher performance.

In addition to the personal computer 1100 (mobile personal computer) in FIG. 8A, the mobile phone 1200 in FIG. 8B, and the digital camera 1300 in FIG. 9, the vibrating element 1 as an electronic component according to the embodiment of the invention can be applied to electronic apparatuses such as, for example, inkjet ejection apparatuses (for example, inkjet printers), laptop personal computers, television sets, video camcorders, car navigation systems, pagers, electronic notebooks (including those with communication function), electronic dictionaries, calculators, electronic gaming machines, workstations, videophones, surveillance television monitors, electronic binoculars, POS terminals, medical apparatuses (for example, electronic thermometers, sphygmomanometers, blood glucose meters, electrocardiogram measuring systems, ultrasonic diagnosis apparatuses, and electronic endoscopes), fishfinders, various types of measuring instrument, indicators (for example, indicators used in vehicles, aircraft, and ships), and flight simulators.

### Moving Object

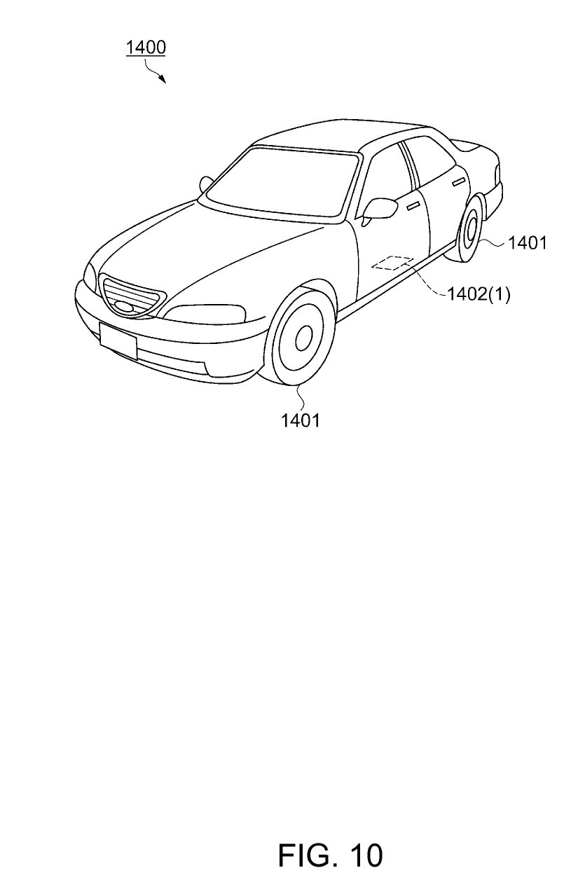

Next, a moving object according to an embodiment of the invention, to which the vibrating element 1 is applied, will be described based on FIG. 10.

FIG. 10 is a perspective view showing a configuration of an automobile 1400 as a moving object including the vibrating element 1 according to the embodiment of the invention.

A gyro sensor that is configured to include the vibrating element 1 according to the invention is mounted in the automobile 1400. For example, as shown in the drawing, an electronic control unit (ECU) 1402 into which the gyro sensor that controls tires 1401 is built is mounted in the automobile 1400 as a moving object. As other examples, the vibrating element 1 can be widely applied to an electronic control unit such as for, for example, keyless entry systems, immobilizers, car navigation systems, car air-conditioners, anti-lock brake systems (ABSs), air bags, tire pressure monitoring systems (TPMSs), engine control, battery monitors of hybrid and electric automobiles, and car body attitude control systems.

As described above, the vibrating element 1 that suppresses the occurrence of unnecessary vibration and has a high Q value is utilized, whereby it is possible to provide a moving object with higher performance.

The vibrating element 1, the electronic device 2, the electronic apparatuses 1100, 1200, and 1300, and the moving object 1400 according to the embodiments of the invention have been described based on the embodiments shown in the drawings. However, an embodiment of the invention is not limited to these embodiments. The configuration of each part can be replaced with any configuration having a similar function. Moreover, any other configurations may be added to the embodiments of the invention. Moreover, the embodiments described above may be appropriately combined with each other.

The entire disclosure of Japanese Patent Application No. 2014-021138, filed Feb. 6, 2014 is expressly incorporated by reference herein.

What is claimed is:

1. A method for manufacturing a vibrating element including
a vibrating arm,
a groove portion provided in the vibrating arm,
a first thickened portion provided on one side of the groove portion in a direction intersecting an extending direction of the vibrating arm, in a plan view of the vibrating arm, and a second thickened portion provided on the side opposite to the one side, the method comprising:
providing, on a substrate, a first protective layer for forming the first thickened portion and a second protective layer for forming the second thickened portion;
disposing the substrate in an apparatus including an energy-beam emitting unit for dry etching; and
etching, using an energy beam emitted from the energy-beam emitting unit, the substrate on which the first protective layer and the second protective layer are disposed on one side relative to an intersection point at which a center of the energy-beam emitting unit and the substrate intersect each other in a plan view of the substrate, wherein
when a distance between the intersection point and the first protective layer is shorter than a distance between the intersection point and the second protective layer, a width of the first protective layer in a direction intersecting the extending direction of the vibrating arm is narrower than a width of the second protective layer in the direction intersecting the extending direction of the vibrating arm.

2. The method for manufacturing the vibrating element according to claim 1, further comprising:
providing a third protective layer between the first protective layer and the second protective layer in the plan view of the substrate; and
forming at least a portion of an outer shape of the vibrating arm using the energy beam.

3. The method for manufacturing the vibrating element according to claim 1, further comprising:
providing, before the forming of the protective layers, a third protective layer for forming an outer shape of the vibrating arm; and
forming at least a portion of the outer shape of the vibrating arm using the energy beam.

4. The method for manufacturing the vibrating element according to claim 1, wherein the substrate is a quartz crystal substrate.

5. The method for manufacturing the vibrating element according to claim 2, wherein the substrate is a quartz crystal substrate.

6. The method for manufacturing the vibrating element according to claim 3, wherein the substrate is a quartz crystal substrate.

7. The method for manufacturing the vibrating element according to claim 4, wherein the extending direction of the vibrating arm is along a Y-axis direction of the quartz crystal substrate.

8. The method for manufacturing the vibrating element according to claim 5, wherein the extending direction of the vibrating arm is along a Y-axis direction of the quartz crystal substrate.

9. The method for manufacturing the vibrating element according to claim 6, wherein the extending direction of the vibrating arm is along a Y-axis direction of the quartz crystal substrate.

10. A vibrating element comprising:
a vibrating arm;
a groove portion provided in the vibrating arm;
a first thickened portion provided on one side of the groove portion in a direction intersecting an extending direction of the vibrating arm, in a plan view of the vibrating arm, and a second thickened portion provided on the side opposite to the one side, the first thickened portion having a width narrower than a width of the second thickened portion; and
an inclined portion provided at an outside surface of the first thickened portion in a cross-sectional view intersecting the extending direction of the vibrating arm.

11. An electronic device comprising:
the vibrating element according to claim 10; and
a circuit element.

12. An electronic apparatus comprising the vibrating element according to claim 10.

13. A moving object comprising the vibrating element according to claim 10.
